(19) United States
(12) Patent Application Publication
(10) Pub. No.: US 2020/0243305 A1
(43) Pub. Date: Jul. 30, 2020

(54) Post Plasma Gas Injection In A Separation Grid

(71) Applicants: Mattson Technology, Inc., Fremont, CA (US); Beijing E-Town Semiconductor Technology, Co., LTD, Beijing (CN)

(72) Inventors: Weimin Zeng, San Jose, CA (US); Chun Yan, San Jose, CA (US); Dixit V. Desai, Pleasanton, CA (US); Hua Chung, Saratoga, CA (US); Michael X. Yang, Palo Alto, CA (US); Peter Lembesis, Boulder Creek, CO (US); Ryan M. Pakulski, Brentwood, CA (US); Martin Zucker, Orinda, CA (US)

(21) Appl. No.: 16/744,244

(22) Filed: Jan. 16, 2020

Related U.S. Application Data
(60) Provisional application No. 62/796,746, filed on Jan. 25, 2019.
(60) Provisional application No. 62/861,423, filed on Jun. 14, 2019.

(51) Int. Cl. H01J 37/32

(52) U.S. Cl. CPC H01J 37/32449; H01L 21/67017; H01J 37/32834; H01J 37/32715

(57) ABSTRACT

A plasma process apparatus is provided. The plasma processing apparatus includes a plasma chamber and a processing chamber. The processing chamber includes a substrate holder operable to support a substrate. The plasma processing apparatus further includes a separation grid separating the plasma chamber from the processing chamber. The separation grid includes a gas delivery system. The gas delivery system defines a channel, an inlet and a plurality of outlets in fluid communication with the inlet via the channel. The gas delivery system is configured to reduce non-uniformities associated with a treatment process performed on the substrate.

### PRIORITY CLAIM

The present application is based on and claims priority to U.S. Provisional Application No. 62/796,746, titled “Post Plasma Gas Injection in a Separation Grid,” having a filing date of Jan. 25, 2019, which is incorporated by reference herein. The present application is also based on and claims priority to U.S. Provisional Application No. 62/861,423, titled “Post Plasma Gas Injection in a Separation Grid,” having a filing date of Jun. 14, 2019, which is incorporated by reference herein.

### FIELD

The present disclosure relates generally to a plasma processing apparatus and, more specifically, a post plasma gas injection in a separation grid of the plasma processing apparatus.

### BACKGROUND

Plasma processing is widely used in the semiconductor industry for deposition, etching, resist removal, and related processing of semiconductor wafers and other workpieces. Plasma sources (e.g., microwave, ECR, inductive, etc.) are often used for plasma processing to produce high density plasma and reactive species for processing workpieces. Plasma processing apparatus can be used for strip processes, such as photoresist removal. Plasma strip tools can include a plasma chamber where plasma is generated and a separate processing chamber where the workpiece is processed. The processing chamber can be “downstream” of the plasma chamber such that there is no direct exposure of the workpiece to the plasma. A separation grid can be used to separate the processing chamber from the plasma chamber. The separation grid can be transparent to neutral particles but not transparent to charged particles from the plasma. The separation grid can include one or more sheets of material with holes.

### SUMMARY

Aspects and advantages of embodiments of the present disclosure will be set forth in part in the following description, or may be learned from the description, or may be learned through practice of the embodiments.

A plasma process apparatus is provided. The plasma processing apparatus includes a plasma chamber and a processing chamber. The processing chamber includes a workpiece holder operable to support a workpiece. The plasma processing apparatus further includes a separation grid separating the plasma chamber from the processing chamber. The separation grid includes a gas delivery system. The gas delivery system defines a channel, an inlet and a plurality of outlets in fluid communication with the inlet via the channel. The gas delivery system is configured to reduce non-uniformities associated with a treatment process performed on the workpiece.

In another aspect, a plasma processing apparatus is provided. The plasma processing apparatus includes a plasma chamber and a processing chamber. The processing chamber includes a substrate holder operable to support a substrate. The plasma processing apparatus further includes a separation grid and a plurality of independently controllable valves. The separation grid separates the plasma chamber from the processing chamber. The separation grid includes gas delivery system. The gas delivery system defines a plurality of channels, a plurality of inlets, and a plurality of outlets. Each inlet of the plurality of inlets is coupled to a corresponding valve of the plurality of independently controllable valves. Furthermore, the gas delivery system is configured such that gas exiting the channel via the plurality of outlets reduces non-uniformities associated with a treatment process performed on the substrate.

In yet another aspect, a plasma processing apparatus is provided. The plasma processing apparatus includes a processing chamber and a workpiece holder in the processing chamber. The workpiece holder is operable to support a first workpiece and a second workpiece. The workpiece holder includes a first processing station and a second processing station. The first processing station is configured to support the first workpiece. The second processing station is configured to support the second workpiece. The plasma processing apparatus includes a pump port configured to evacuate gases from the processing chamber. The pump port is located beneath the workpiece holder. The workpiece holder defines an opening located between the first processing station and the second processing station. The opening provides path to evacuate gases from the processing chamber to the pump port. The opening includes a plurality of holes.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example plasma processing apparatus according to example embodiments of the present disclosure;

FIG. 2 depicts post plasma gas injection according to example embodiments of the present disclosure;

FIG. 3 depicts a top view of a separation grid of a plasma processing apparatus according to example embodiments of the present disclosure;

FIG. 4 depicts a top view of a gas delivery system of a separation grid according to example embodiments of the present disclosure;

FIG. 5 depicts a flow of gas through a gas delivery system of a separation grid according to example embodiments of the present disclosure;

FIG. 6 depicts a top view of a gas delivery system according to example embodiments of the present disclosure;

FIG. 7 depicts a top view of a gas delivery system according to example embodiments of the present disclosure;

FIG. 8 depicts a top view of a gas delivery system according to example embodiments of the present disclosure;

FIG. 9 depicts a top view of a gas delivery system according to example embodiments of the present disclosure;

FIG. 10 depicts a top view of a gas delivery system according to example embodiments of the present disclosure;

FIG. 11 depicts a top view of a gas delivery system according to example embodiments of the present disclosure;

FIG. 12 depicts a top view of a gas delivery system according to example embodiments of the present disclosure;

FIG. 13 depicts a flow of gas through a gas delivery system of a separation grid according to example embodiments of the present disclosure;

FIG. 14 depicts a top view of a gas delivery system according to example embodiments of the present disclosure;

FIG. 15 depicts a block diagram of components of a separation grid according to example embodiments of the present disclosure;

FIG. 16 depicts a flow of gas through a gas delivery system of a separation grid according to example embodiments of the present disclosure;

FIG. 17 depicts a top view of a gas delivery system according to example embodiments of the present disclosure;

FIG. 18 depicts a top view of a gas delivery system according to example embodiments of the present disclosure;

FIG. 19 depicts a top view of a gas delivery system according to example embodiments of the present disclosure;

FIG. 20 depicts a top view of a gas delivery system according to example embodiments of the present disclosure;

FIG. 21 depicts an example twin chamber plasma processing apparatus according to example embodiments of the present disclosure;

FIG. 22 depicts a plan view of an example processing chamber of a twin chamber plasma processing apparatus according to example embodiments of the present disclosure;

FIG. 23 depicts a plan view of an example processing chamber of a twin chamber plasma processing apparatus according to example embodiments of the present disclosure;

FIG. 24 depicts example openings according to example embodiments of the present disclosure;

FIG. 25 depicts example openings according to example embodiments of the present disclosure;

FIG. 26 depicts example openings according to example embodiments of the present disclosure; and

FIG. 27 depicts example openings according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to a plasma processing apparatus. A plasma processing apparatus can include a plasma chamber where a plasma is generated using a plasma source, such as an inductively coupled plasma source. The plasma processing apparatus can include a processing chamber. The processing chamber can include a workpiece holder (e.g., a pedestal) to support a workpiece. The plasma chamber and processing chamber can be separated by a separation grid. According to example aspects of the present disclosure, the plasma processing apparatus can include gas inlets for injecting gas into post-plasma mixtures at or below the separation grid (e.g., post plasma gas injection “PPGI”).

For instance, in some embodiments, the separation grid can include a gas delivery system. The gas delivery system can define a channel, an inlet, and a plurality of outlets. Each outlet of the plurality of outlets can be in fluid communication with the inlet via the channel. In this manner, a gas associated with post-plasma gas injection can enter and exit the channel via the inlet and outlets, respectively. As will be discussed below in more detail, the gas delivery system of the separation grid can be configured to reduce or eliminate non-uniformities associated with a treatment process (e.g., etching process, strip treatment process, surface treatment process, etc.) performed on the workpiece disposed in the processing chamber.

In some implementations, the portion of the channel defined by the first portion of the gas delivery system can be different than the portion of the channel defined by the second portion of the gas delivery system. For example, the width of the portion of the channel defined by the first portion can be less than the width of the portion of the channel defined by the second portion. In this manner, the portion of the channel defined by the first portion can be narrower than the portion of the channel defined by the second portion. In alternative implementations, the width of the portion of the channel defined by the first portion can be greater than the width of the portion of the channel defined by the second portion. In this manner, the portion of the channel defined by the first portion can be wider than the portion of the channel defined by the second portion.

In some implementations, the inlet can be defined by the first portion of the gas delivery system. Additionally, the plurality of outlets can include a first group of outlets and a second group of outlets. The first group of outlets can be defined by the first portion. The second group of outlets can be defined by the second portion. In some implementations, a diameter of the first group of outlets can be different than a diameter of the second group of outlets. For instance, the diameter of each outlet included in the first group of outlets can be less (e.g., smaller) than the diameter of each outlet included in the second group of outlets. In this manner, the volume of gas exiting the channel via the outlets defined by the second portion of the gas delivery system can be greater than the volume of gas exiting the channel via the outlets defined by the first portion of the gas delivery system. In alternative implementations, the diameter of each outlet included in the first group of outlets can be greater (e.g., larger) than the diameter of each outlet included in the second group of outlets. In this manner, the volume of gas exiting the channel via the first group of outlets can be greater than the volume of gas exiting the channel via the second group of outlets.

In some implementations, the number of outlets defined by the first portion of the gas delivery system can be less than the number of outlets defined by the second portion of the gas delivery system. In this manner, an amount of gas exiting the channel via the outlets defined by the second portion of the gas delivery system can be greater than an amount of gas exiting the channel via the outlets defined by the first portion of the gas delivery system. In alternative implementations, the number of outlets defined by the first portion of the gas delivery system can be greater than the number of outlets defined by the second portion of the gas delivery system. In this manner, an amount of gas exiting the channel via the outlets defined by the first portion of the gas delivery system can be greater than an amount of gas exiting the channel via the outlets defined by the second portion of the gas delivery system.

In some implementations, a blocking material can be placed over one or more outlets of the plurality of outlets. For example, the blocking material can be placed over the outlets defined by the first portion of the gas delivery system. Thus, gas within the channel must exit the channel via the outlets defined by a second portion of the gas delivery system. Alternatively, the blocking material can be placed over the outlets defined by the second portion such that the gas within the channel must exit the channel via the outlets defined by the first portion. In this manner, the flow of gas exiting the channel can be made asymmetric which, in some instances, may be desirable to reduce non-uniformities associated with the treatment process performed on the workpiece.

In some implementations, the gas delivery system can include a wall dividing the channel into a first channel and a second channel. The wall can define a plurality of openings to provide fluid communication between first channel and the second channel. In this manner, gas entering the first channel via the inlet can enter the second channel in a uniform manner. The gas can then exit the second channel via the plurality of openings in a more uniform manner, which can reduce or eliminate non-uniformities associated with the treatment process performed on the workpiece.

In some implementations, the gas delivery system can define a plurality of channels. For example, the gas delivery system can define a first channel, a second channel, a third channel and a fourth channel. It should be appreciated, however, that the gas delivery system can be configured to define more or fewer channels. The gas delivery system can further define a plurality of inlets. For instance, the gas delivery system can define a first inlet, a second inlet, a third inlet, and a fourth inlet. It should be appreciated, however, that the gas delivery system can define more or fewer inlets. The first inlet can be in fluid communication with the first channel. The second inlet can be in fluid communication with the second channel. The third inlet can be in fluid communication with the third channel. The fourth inlet can be in fluid communication with the fourth channel.

In some implementations, the gas delivery system can define a plurality of outlets. For instance, the gas delivery system can define a first plurality of outlets, a second plurality of outlets, a third plurality of outlets and a fourth plurality of outlets. The first plurality of outlets can be in fluid communication with the first inlet via the first channel. The second plurality of outlets can be in fluid communication with the second inlet via the second channel. The third plurality of outlets can be in fluid communication with the third inlet via the third channel. The fourth plurality of outlets can be in fluid communication with the fourth inlet via the fourth channel. As will be discussed below in more detail, the flow of gas into the plurality of channels (e.g., first channel, second channel, third channel, and fourth channel) can be controlled to control uniformity (e.g., azimuthal uniformity control) of the treatment process performed on the workpiece.

In some implementation, the plasma processing apparatus can include a plurality of independently controlled valves configured to regulate a flow of gas into the plurality of channels defined by the gas delivery system. For instance, the plurality of valves can include a first valve, a second valve, a third valve, and a fourth valve. It should be appreciated, however, that more or fewer valves can be used. In some implementations, each of the plurality of valves (e.g., first valve, second valve, third valve, fourth valve) is coupled between a gas supply and a corresponding inlet of the plurality of inlets. For instance, the first valve can be coupled between the gas supply and the first inlet. The second valve can be coupled between the gas supply and the second inlet. The third valve can be coupled between the gas supply and the third inlet. Finally, the fourth valve can be coupled between the gas supply and the fourth inlet.

In some implementations, each valve of the plurality of valves can be movable between an open position and a closed position (e.g., or somewhere in between) to regulate the flow of gas into a corresponding channel of the gas delivery system. For instance, gas can flow from the gas supply to the first channel when the first valve is in the open position. Conversely, gas cannot flow from the gas supply to the first channel when the first valve is in the closed position. As such, a position (e.g., open or closed) of the plurality of valves can be controlled as needed to control the manner in which gas is provided to the gas delivery system. In this manner, gas can enter and exit one or more channels as needed to reduce or eliminate non-uniformities associated with the treatment process performed on the workpiece.

The separation grid according to the present disclosure provides numerous technical benefits. For instance, the separation grid can be configured to reduce or eliminate non-uniformities associated with a treatment process performed on the workpiece within the processing chamber. In this manner, the treatment process can be improved and/or more precisely controlled.

Example aspects of the present disclosure are discussed with reference to treating a semiconductor wafer workpiece for purposes of illustration and discussion. Those of ordinary skill in the art, using the disclosures provided herein, will understand that aspects of the present disclosure can be used in conjunction with the processing of other workpieces without deviating from the scope of the present disclosure. Example workpieces include glass plates, films, ribbons, solar panels, mirrors, liquid crystal displays, semiconductor wafers, and the like. As used herein, the use of the term “about” in conjunction with a numerical value can refer to within 20% of the stated numerical value.

Example Plasma Processing Apparatus with Separation Grid Having Gas Delivery System

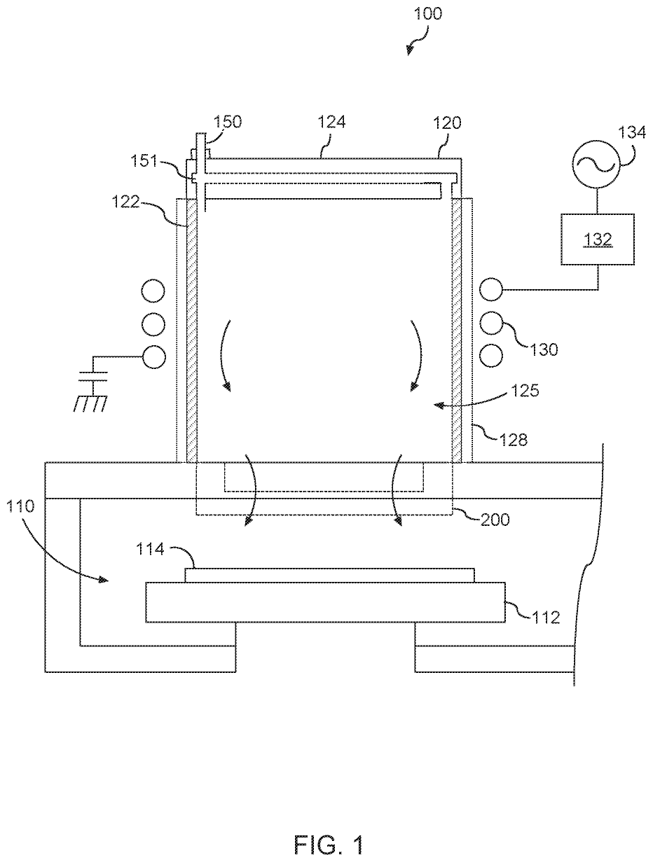

With reference now to the FIGS., FIG. 1 depicts a plasma processing apparatus 100 according to example embodiments of the present disclosure. The plasma processing apparatus 100 can include a processing chamber 110 and a plasma chamber 120. The processing chamber 110 can be separated from the plasma chamber 120 via a via a separation grid 200 of the plasma processing apparatus 100. The plasma processing apparatus 100 can further include a workpiece holder or pedestal 112 disposed within the processing chamber 110. The pedestal 112 can be configured to support a workpiece 114.

The plasma chamber 120 can include a sidewall 122 formed from any suitable dielectric material (e.g., quartz). The plasma chamber 120 can further include a ceiling 124 supported, at least in part, by the sidewall 122. As shown, an interior 125 of the plasma chamber 120 can be defined, at least in part, by the separation grid 116, sidewall 122 and ceiling 124.

The plasma processing apparatus 100 can include an induction coil 130 disposed adjacent an exterior surface of the sidewall 122 of the plasma chamber 120. The induction coil 130 can be coupled to an RF power generator 134 through a suitable matching network 132. Reactant and carrier gases can be provided to the interior 125 of the plasma chamber 120 via a gas supply 150. When the induction coil 130 is energized with RF power from the RF power generator 134, a substantially inductive plasma is induced in the plasma chamber 120. In a particular embodiment, the plasma processing apparatus 100 can include a grounded Faraday shield 128 to reduce capacitive coupling of the induction coil 130 to the plasma.

In some implementations, the inductive plasma (i.e., plasma generation region) and desired particles (e.g., neutral particles) can flow from the plasma chamber 120 to the workpiece 114 via a plurality of holes (not shown) defined by the separation grid 200. The separation grid 200 can be used to perform ion filtering of particles generated by plasma in the plasma chamber 120. Particles passing through the separation grid 116 can be exposed to the workpiece 114 (e.g. a semiconductor wafer) in the processing chamber 110 for surface treatment of the workpiece (e.g., photoresist removal).

More particularly, in some embodiments, the separation grid 200 can be transparent to neutral species but not transparent to charged particles from the plasma. For example, charged particles or ions can recombine on walls of the separation grid 200. The separation grid 200 can include one or more grid plates of material with holes distributed according to a hole pattern for each sheet of material. The hole patterns can be the same or different for each grid plate.

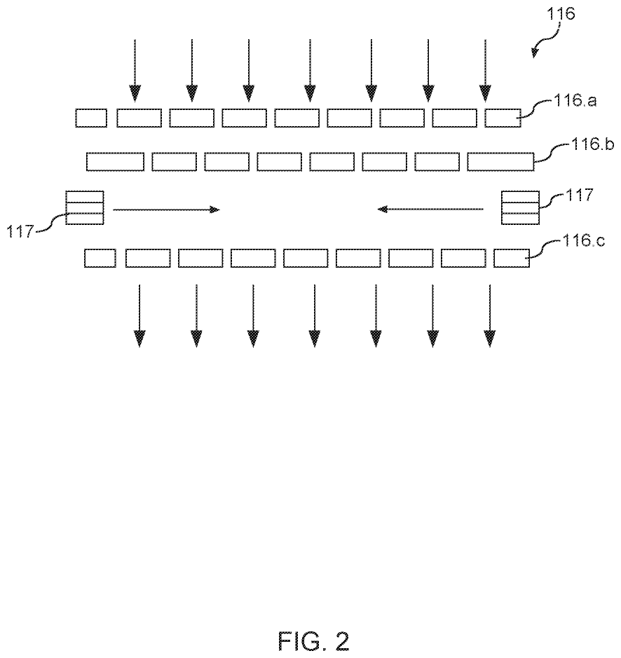

FIG. 2 depicts an example separation grid 116 configured for post plasma gas injection according to example embodiments of the present disclosure. More particularly, the separation grid assembly 116 includes a first grid plate 116a and a second grid plate 116b disposed in parallel relationship for ion/UV filtering.

The first grid plate 116a and a second grid plate 116b can be in parallel relationship with one another. The first grid plate 116a can have a first grid pattern having a plurality of holes. The second grid plate 116b can have a second grid pattern having a plurality of holes. The first grid pattern can be the same as or different from the second grid pattern. Charged particles (e.g., ions) can recombine on the walls in their path through the holes of each grid plate 116a, 116b in the separation grid 116. Neutral species (e.g., radicals) can flow relatively freely through the holes in the first grid plate 116a and the second grid plate 116b.

Subsequent to the second grid plate 116b, a gas injection source 117 (e.g., gas port) can be configured to admit a gas into the radicals. The radicals can then pass through a third grid plate 116c for exposure to the workpiece. The gas can be used for a variety of purposes. For instance, in some embodiments, the gas can be a neutral gas or inert gas (e.g., nitrogen, helium, argon). The gas can be used to cool the radicals to control energy of the radicals passing through the separation grid. In some embodiments, a vaporized solvent can be injected into the separation grid 116 via the gas injection source 117 or another gas injection source (not shown). In some embodiments, desired molecules (e.g., hydrocarbon molecules) can be injected into the radicals.

The post plasma gas injection illustrated in FIG. 2 is provided for example purposes. Those of ordinary skill in the art will understand that there are a variety of different configurations for implementing one or more gas ports in a separation grid for post plasma gas injection according to example embodiments of the present disclosure. The one or more gas ports can be arranged between any grid plates, can inject gas or molecules in any direction, and can be used to for multiple post plasma gas injection zones at the separation grid for uniformity control.

It should be appreciated that the separation grid 116 can include any suitable number of grid plates. For instance, as shown in FIG. 2, the separation grid 16 can include three separate grid plates (e.g., first grid plate 116a, second grid plate 116b, third grid plates 116c). In alternative implementations, the separation grid 116 can include more or fewer grid plates. For instance, in some implementations, the separation grid 116 can include the first grid plate 116a and the third grid plate 116c. In such implementations, the gas injection source 117 can be configured to admit a gas into radicals flowing from the first grid plate 116a to the third grid plate 116c.

For instance, certain example embodiments can inject a gas or molecules at a separation grid in a center zone and a peripheral zone. More zones with gas injection at the separation grid can be provided without deviating from the scope of the present disclosure, such as three zones, four zones, five zones, six zones, etc. The zones can be partitioned in any manner, such as radially, azimuthally, or in any other manner. For instance, in one example, post plasma gas injection at the separation grid can be divided into a center zone and four azimuthal zones (e.g., quadrants) about the periphery of the separation grid.

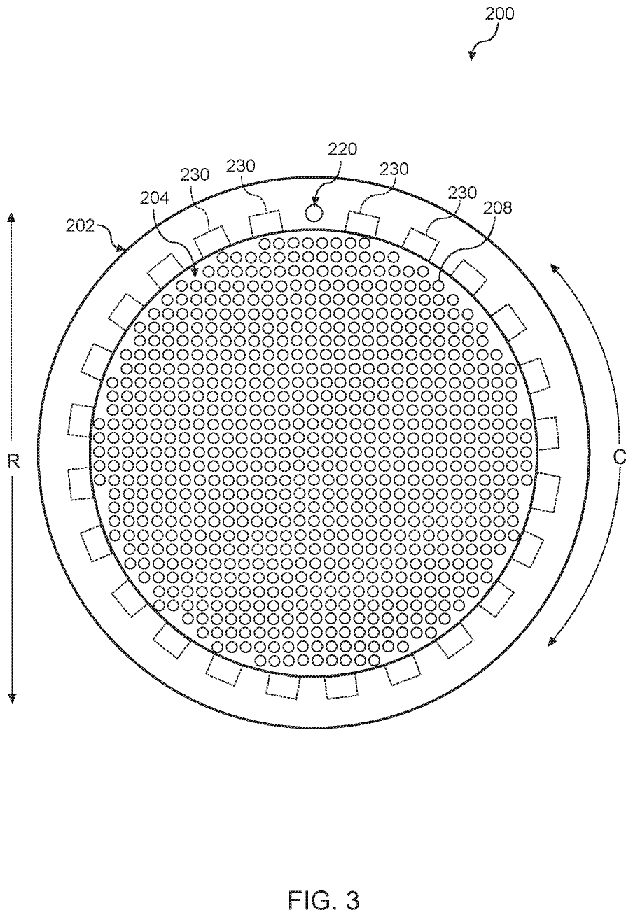

Referring now to FIG. 3, an example embodiment of the separation grid 200 is provided according to the present disclosure. As shown, the separation grid 200 can have an annular shape. It should be appreciated, however, that the separation grid 200 can have any suitable shape. For instance, in some implementations, the separation grid 200 may have a square shape or rectangular shape.

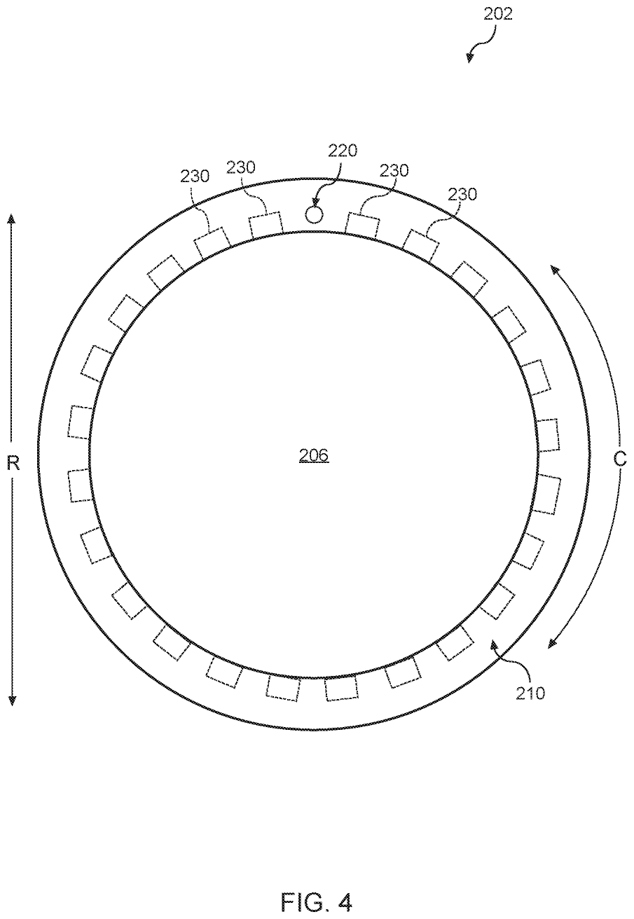

As shown, the separation grid 200 can define a coordinate system comprising a radial direction R and a circumferential direction C. The separation grid 200 can include a gas delivery system 202. The separation grid 200 can also include a surface 204 disposed within an opening 206 (FIG. 4) defined by the gas delivery system 202. As shown, the surface 204 can define a plurality of holes 208. In this manner, neutral radicals within the interior 125 of the plasma chamber 120 can flow into the processing chamber 110 via the holes 208.

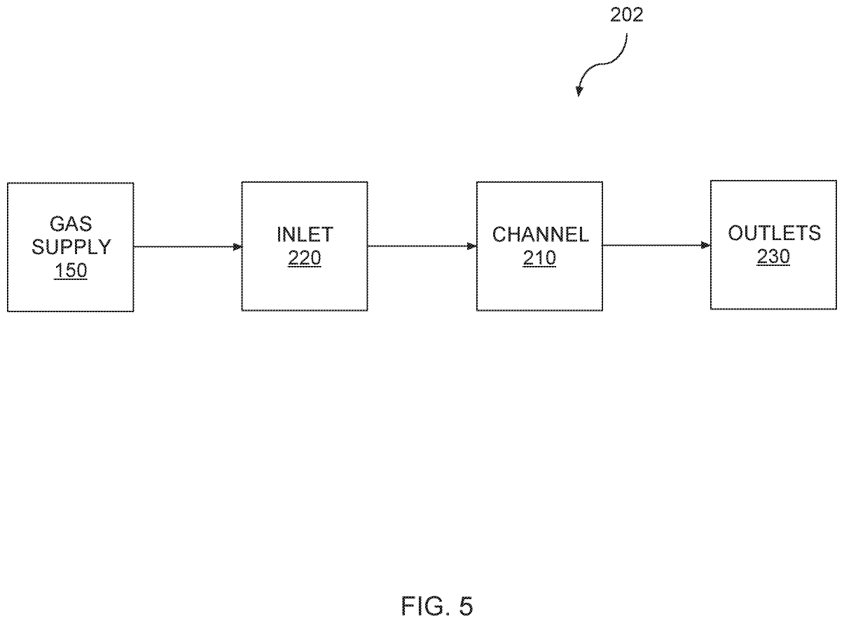

In some implementations, the gas delivery system 202 of the separation grid 200 can define a channel 210, an inlet 220, and a plurality of outlets 230. Each outlet of the plurality of outlets 230 can be in fluid communication with the inlet 220 via the channel 210. Referring briefly now to FIG. 5, in some implementations, the gas supply 150 can be in fluid communication with the inlet 220 of the gas delivery system 202 via one or more conduits. In this manner, gas 300 from the gas supply 150 can be provided to the gas delivery system 202 of the separation grid 200. In particular, the gas 300 can enter and exit the channel 210 of the gas delivery system 202 via the inlet 220 and the plurality of outlets 230, respectively. In some implementations, the gas 300 exiting the channel 210 via the plurality of outlets 230 can flow into the separation grid and/or the processing chamber 110 (FIG. 1) for post plasma gas injection into a mixture of neutral radicals flowing through the separation grid. As will be discussed below, the uniformity of the gas 300 exiting the channel 210 via the plurality of outlets 230 can be controlled to improve uniformity of a treatment process (e.g., etching process, strip treatment process, surface treatment process, etc.) performed on the workpiece 114 (FIG. 1) disposed within the processing chamber 110.

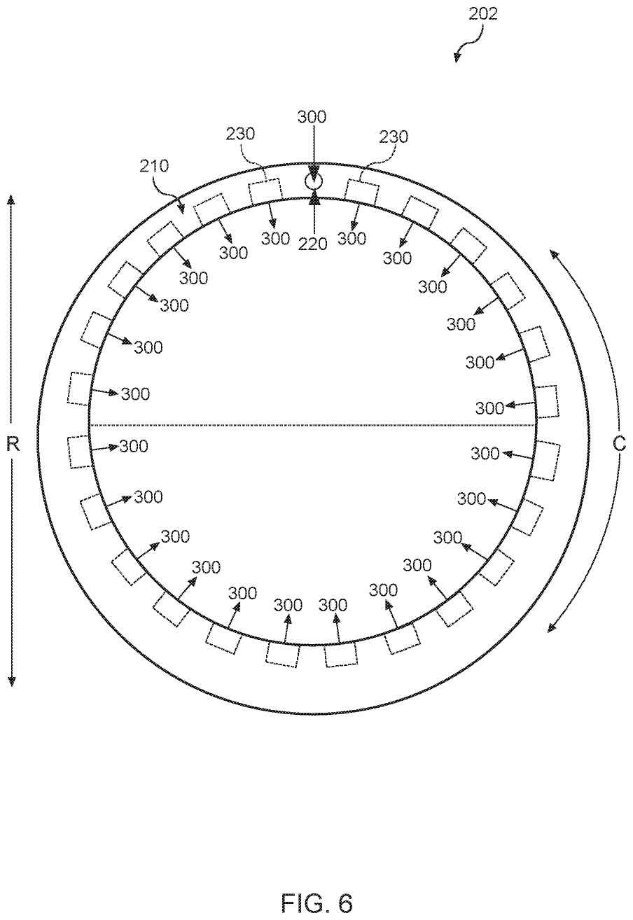

Referring now to FIG. 6, an embodiment of the gas delivery system 202 of the separation grid 200 (FIG. 3) is provided. As shown, the inlet 220 can be defined by the first portion (e.g., above the dashed line along the radial direction R) of the gas delivery system 202. As will be discussed below in more detail, the portion of the channel 210 defined by the first portion of the gas delivery system 202 can be different than the portion of the channel 210 defined by the second portion (e.g., below the dashed line along the radial direction R) of the gas delivery system 202.

In some implementations, the width of the portion of the channel 210 defined by the first portion can be less than the width of the portion of the channel 210 defined by the second portion. In this manner, the portion of the channel 210 defined by the first portion can be narrower than the portion of the channel 210 defined by the second portion. In alternative implementations, the width of the portion of the channel 210 defined by the first portion can be greater than the width of the portion of the channel 210 defined by the second portion. In this manner, the portion of the channel 210 defined by the first portion can be wider than the portion of the channel 210 defined by the second portion.

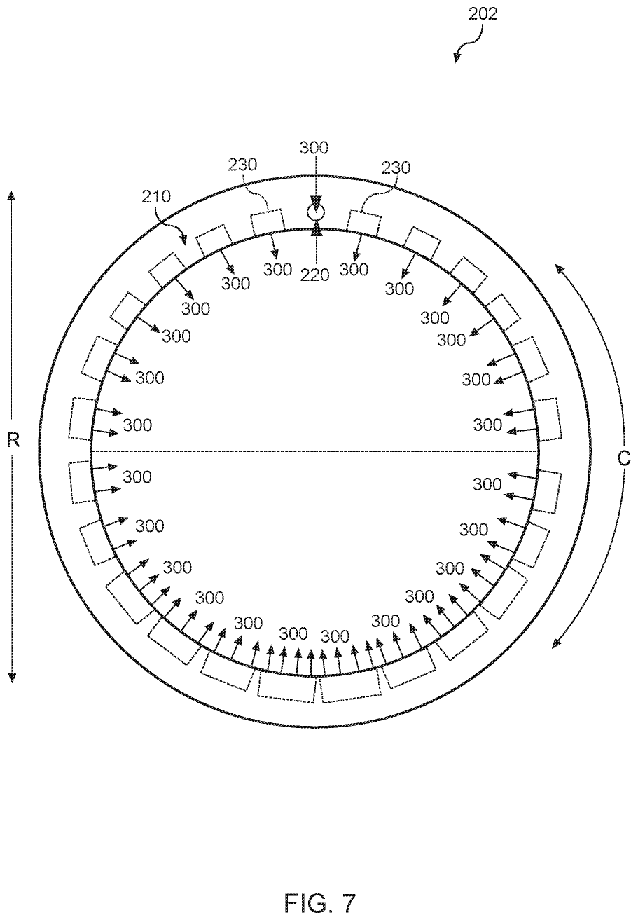

Referring now to FIG. 7, another embodiment of the gas delivery system 202 of the separation grid 200 (FIG. 3) is provided. As shown, the inlet 220 can be defined by the first portion (e.g., above the dashed line along the radial direction R) of the gas delivery system 202. As will be discussed below in more detail, a diameter of the outlets 230 defined by the first portion of the gas delivery system 202 can be different than the diameter of the outlets 230 defined by the second portion (e.g., below the dashed line along the radial direction R) of the gas delivery system 202.

In some implementations, the plurality of outlets 230 can include a first group of outlets and a second group of outlets. The first group of outlets can be defined by the first portion of the gas delivery system 202. The second group of outlets can be defined by the second portion of the gas delivery system 202. In some implementations, a diameter of the first group of outlets can be less (e.g., smaller) than a diameter of the second group of outlets. In this manner, the volume of gas 300 exiting the channel 210 via the second group of outlets can be greater than then volume of gas exiting channel 210 via the first group of outlets. In alternative implementations, the diameter of the first group of outlets can be greater (e.g., larger) than the diameter of the second group of outlets. In this manner, the volume of gas 300 exiting the channel 210 via the first group of outlets can be greater than the volume of gas exiting the channel 210 via the second group of outlets.

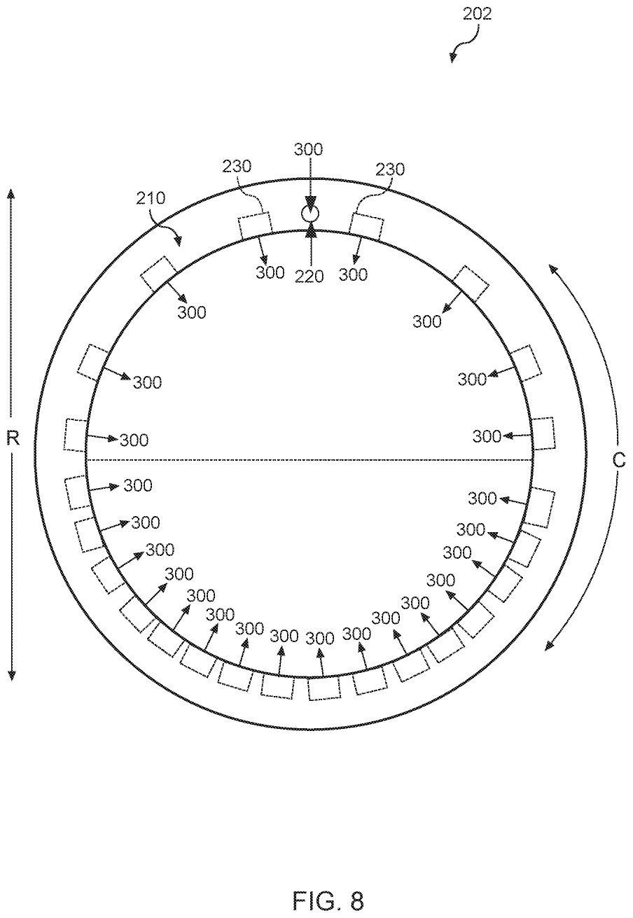

Referring now to FIG. 8, yet another embodiment of the gas delivery system 202 of the separation grid 200 (FIG. 3) is provided. As shown, the inlet 220 can be defined by a first portion (e.g., above the dashed line along the radial direction R) of the gas delivery system 202. As will be discussed below in more detail, the number of outlets 230 defined by the first portion of the gas delivery system 202 can be different than the number of outlets 230 defined by the second portion (e.g., below the dashed line along the radial direction R) of the gas delivery system 202.

In some implementations, the number of outlets 230 defined by the first portion of the gas delivery system 202 can be less than the number of outlets 230 defined by the second portion of the gas delivery system 202. In this manner, an amount of gas 300 exiting the channel 210 via the outlets 230 defined by the second portion of the gas delivery system 202 can be greater than an amount of gas 300 exiting the channel 210 via the outlets 230 defined by the first portion of the gas delivery system 202. In alternative implementations, the number of outlets 230 defined by the first portion of the gas delivery system 202 can be greater than the number of outlets 230 defined by the second portion of the gas delivery system 202. In this manner, an amount of gas 300 exiting the channel 210 via the outlets 230 defined by the first portion of the gas delivery system 202 can be greater than an amount of gas 300 exiting the channel 210 via the outlets 230 defined by the second portion of the gas delivery system 202.

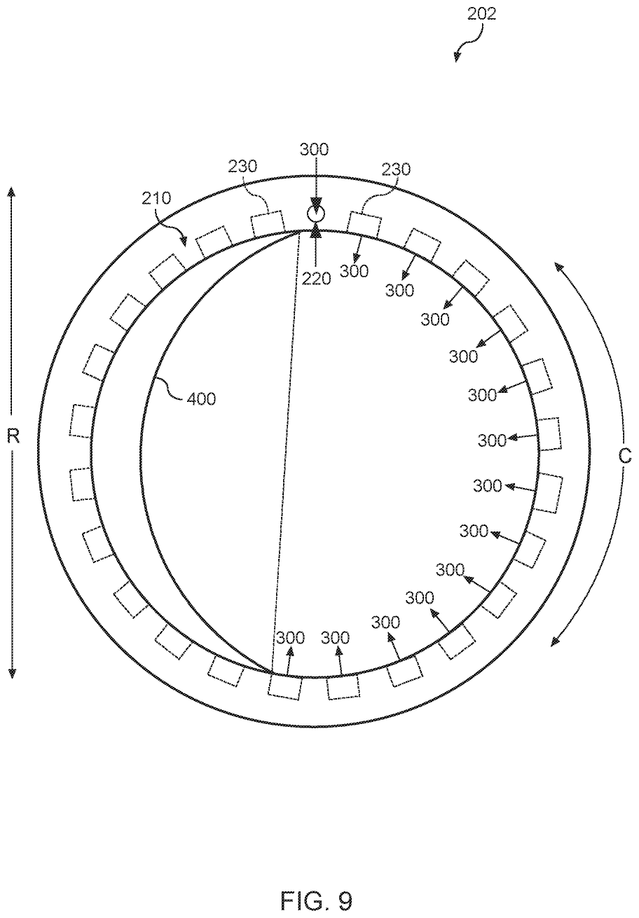

Referring now to FIGS. 9 through 12, various embodiments of the separation grid 200 (FIG. 3) are provided according to example embodiments of the present disclosure. As shown, the inlet 220 can be defined by the first portion (e.g., above the dashed line along the radial direction R) of the gas delivery system 202. As will be discussed below in more detail, one or more outlets of the plurality of outlets 230 can be blocked to adjust the manner in which gas 300 exits the channel 210.

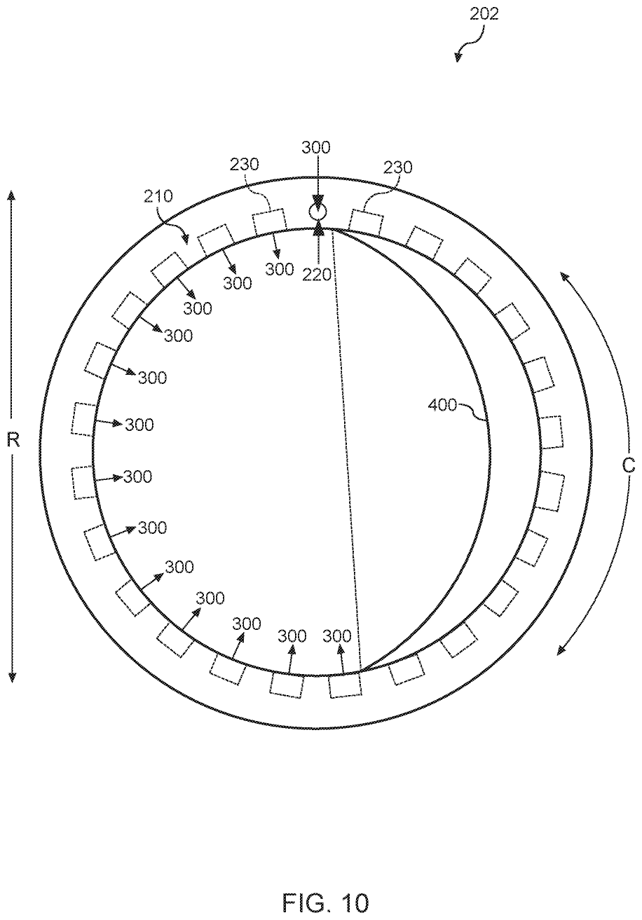

As shown in FIG. 9, a blocking material 400 can be placed over outlets 230 defined by a third portion (e.g., to the left of dashed line) of the gas delivery system 202. In this manner, gas 300 can only exit the channel 210 via outlets 230 defined by a fourth portion (e.g., to the right of dashed line) of the gas delivery system 202. Alternatively, as shown in FIG. 10, the blocking material 400 can be placed over outlets 230 defined by the fourth portion of the gas delivery system 202. In this manner, gas 300 can only exit the channel 210 via outlets 230 defined by the third portion of the gas delivery system 202.

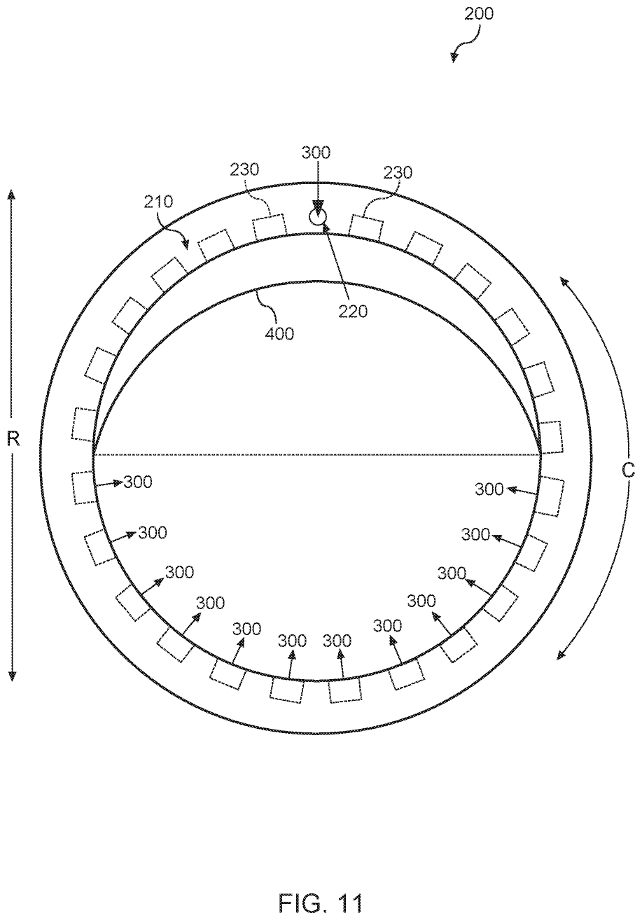

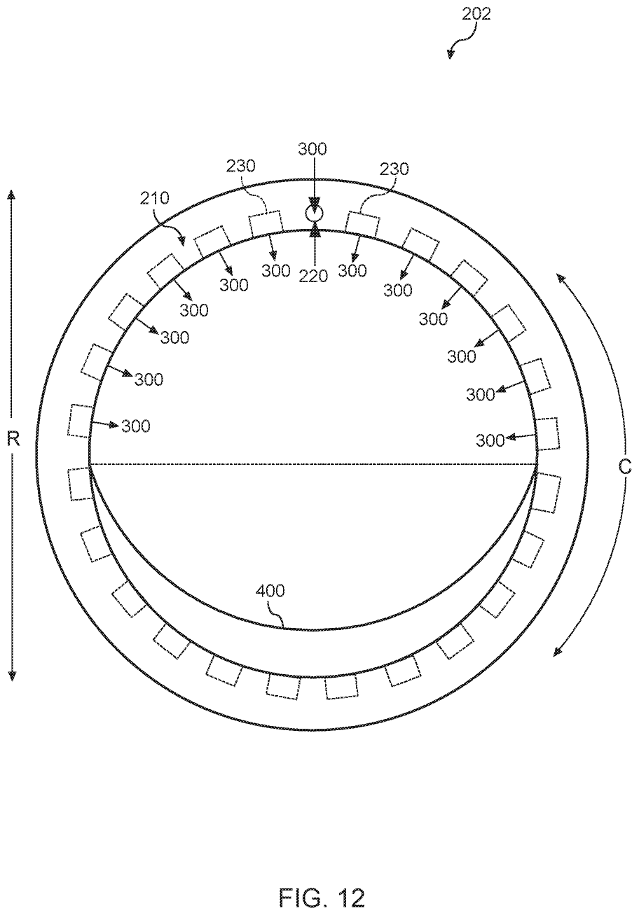

As shown in FIG. 11, the blocking material 400 can be placed over the outlets 230 defined by the first portion (e.g., above the dashed line along the radial direction R) of the gas delivery system 202. In this manner, gas 300 can only exit the channel 210 via the outlets 230 defined by the second portion (e.g., below the dashed line along the radial direction R) of the gas delivery system 202. Alternatively, as shown in FIG. 12, the blocking material 400 can be placed over outlets 230 defined by the second portion of the gas delivery system. In this manner, gas 300 can only exit the channel 210 via outlets 230 defined by the first portion of the gas delivery system 202.

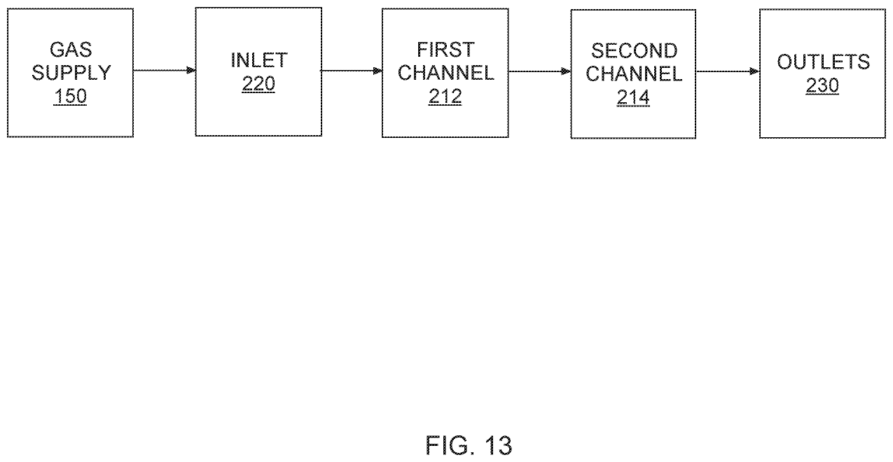

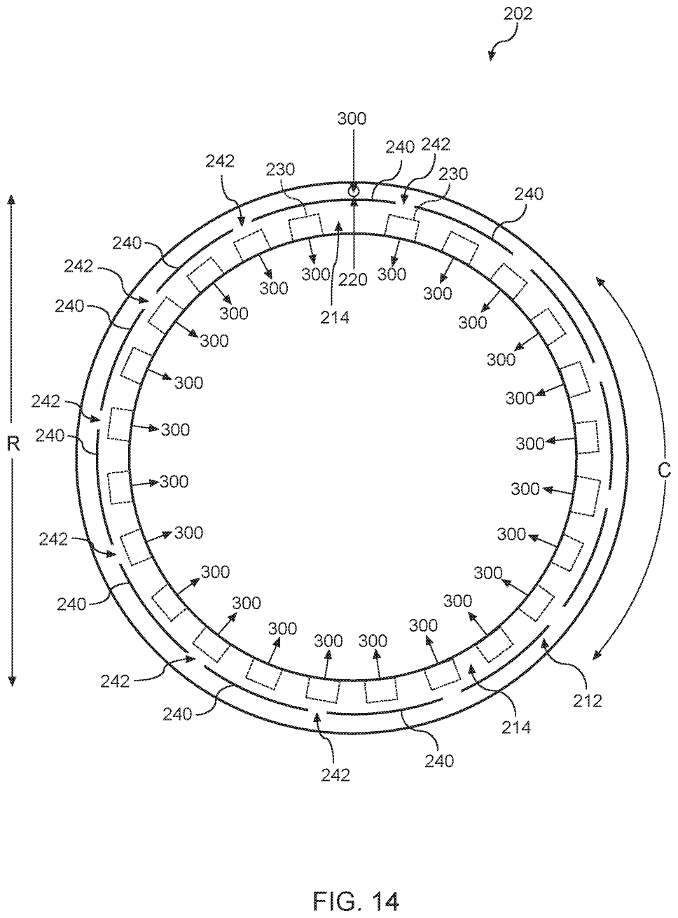

Referring now to FIGS. 13 and 14 in combination, another embodiment of the gas delivery system 202 of the separation grid 200 (FIG. 3) is provided according to example embodiments of the present disclosure. The gas delivery system 202 depicted in FIGS. 13 and 14 can include the same or similar components as the gas delivery system 202 depicted in FIGS. 3 through 5. For instance, the gas delivery system 202 can define an inlet 220 and a plurality of outlets 230. However, in contrast to the gas delivery system depicted in FIGS. 3 through 5, the interior of the gas delivery system 202 depicted in FIGS. 13 and 14 is divided into a first channel 212 and a second channel 214. As will be discussed below in more detail, dividing the interior of the gas delivery system 202 into the first channel 212 and the second channel 214 can improve the uniformity of the treatment process performed on the workpiece 114 (FIG. 1) disposed within the processing chamber 110.

As shown, the inlet 220 can be in fluid communication with the first channel 212. In this manner, gas 300 can enter the first channel 212 via the inlet 220. The gas 300 can then flow from the first channel 212 to the second channel 214 via a plurality of openings 242 in a wall 240 that divides the interior of the gas delivery system into the first channel 212 and the second channel 214. As shown, the plurality of openings 242 spaced apart from one another along the circumferential direction C. In some implementations, the spacing between adjacent openings 242 can be uniform. In this manner, gas 300 can enter the second channel 214 in a more uniform manner. The gas 300 can then exit the second channel 214 via the plurality of outlets 230 and flow into the separation grid 200 and/or the processing chamber 110 (FIG. 1).

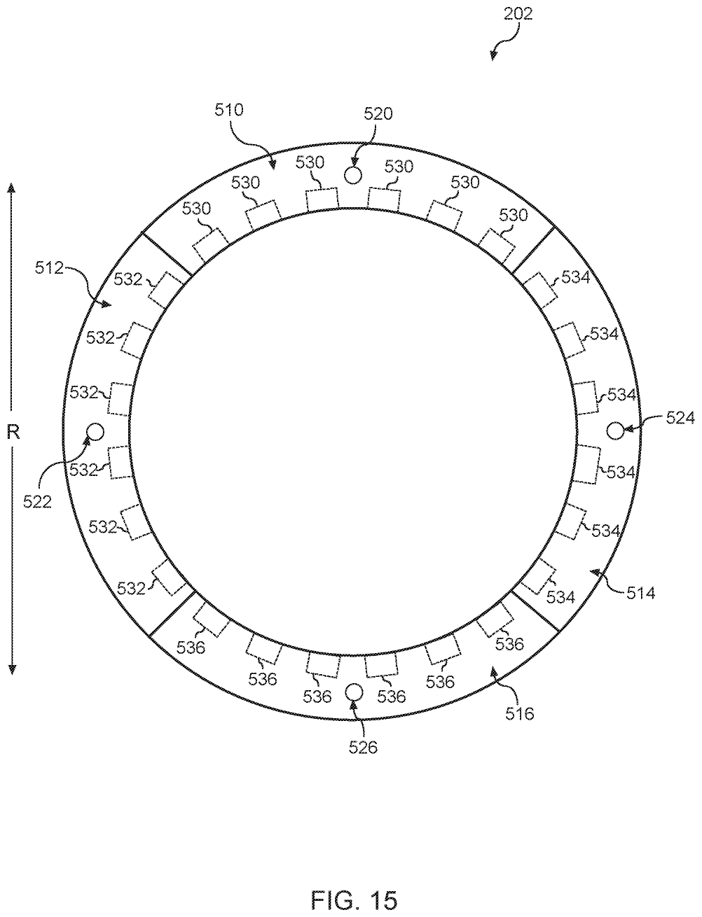

Referring now to FIG. 15, another embodiment of the gas delivery system 202 of the separation grid 200 (FIG. 2) is provided. As shown, the gas delivery system 202 can define a plurality of channels. For instance, the gas delivery system 202 can define a first channel 510, a second channel 512, a third channel 514 and a fourth channel 516. It should be appreciated, however, that the gas delivery system 202 can be configured to define more or fewer channels.

As shown, the gas delivery system 202 can define a plurality of inlets. For instance, the gas delivery system 202 can define a first inlet 520, a second inlet 522, a third inlet 524, and a fourth inlet 526. It should be appreciated, however, that the gas delivery system 202 can define more or fewer inlets. The first inlet 520 can be in fluid communication with the first channel 510. The second inlet 522 can be in fluid communication with the second channel 512. The third inlet 524 can be in fluid communication with the third channel 514. The fourth inlet 526 can be in fluid communication with the fourth channel 516.

The gas delivery system 202 can define a plurality of outlets. For instance, the gas delivery system 202 can define a first plurality of outlets 530, a second plurality of outlets 532, a third plurality of outlets 534 and a fourth plurality of outlets 536. The first plurality of outlets 530 can be in fluid communication with the first inlet 520 via the first channel 510. The second plurality of outlets 532 can be in fluid communication with the second inlet 522 via the second channel 512. The third plurality of outlets 534 can be in fluid communication with the third inlet 524 via the third channel 514. The fourth plurality of outlets 536 can be in fluid communication with the fourth inlet 526 via the fourth channel 516. As will be discussed below in more detail, the flow of gas 300 into the plurality of channels (e.g., first channel 510, second channel 512, third channel 514, and fourth channel 516) can be controlled to improve the uniformity of the plasma etching process performed on the workpiece 114 (FIG. 1).

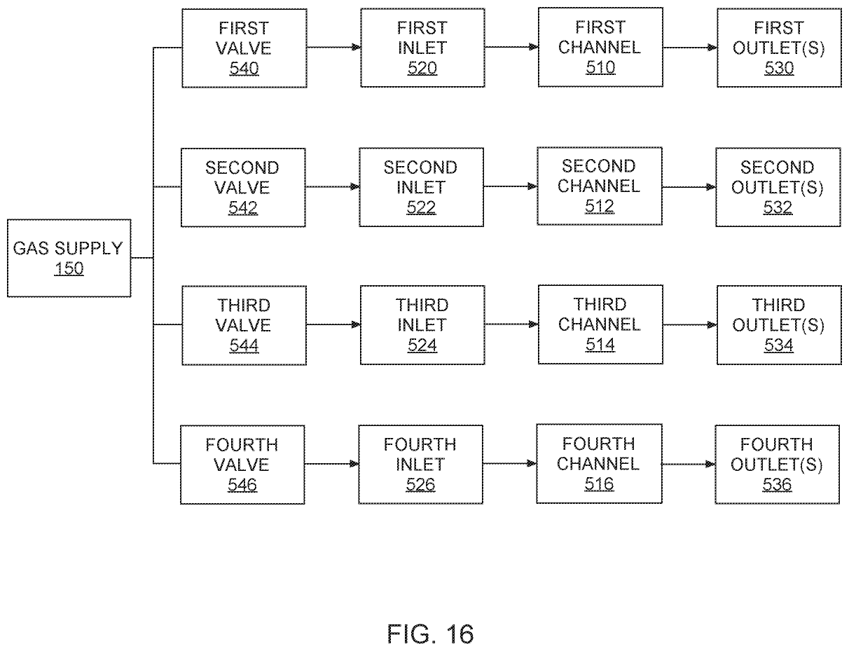

Referring now to FIG. 16, a plurality of independently controllable valves can be used to regulate a flow of gas into the plurality of channels defined by the gas delivery system 202 (FIG. 15). For instance, the plurality of valves can include a first valve 540, a second valve 542, a third valve 544, and a fourth valve 546. It should be appreciated, however, that more or fewer valves can be used. In some implementations, each of the plurality of valves (e.g., first valve 540, second valve 542, third valve 544, fourth valve 546) is coupled between the gas supply 150 and a corresponding inlet of the plurality of inlets. For instance, the first valve 540 can be coupled between the gas supply 150 and the first inlet 520. The second valve 542 can be coupled between the gas supply 150 and the second inlet 522. The third valve 544 can be coupled between the gas supply 150 and the third inlet 524. Finally, the fourth valve 546 can be coupled between the gas supply 150 and the fourth inlet 526. As will be discussed below in more detail, each valve of the plurality of valves 540, 542, 544, 546 can be movable between an open position and a closed position to regulate the flow of gas into a corresponding channel 510, 512, 514, 516 of the gas delivery system 202 (FIG. 14) to allow for post plasma individually controlled gas injection PPIGI.

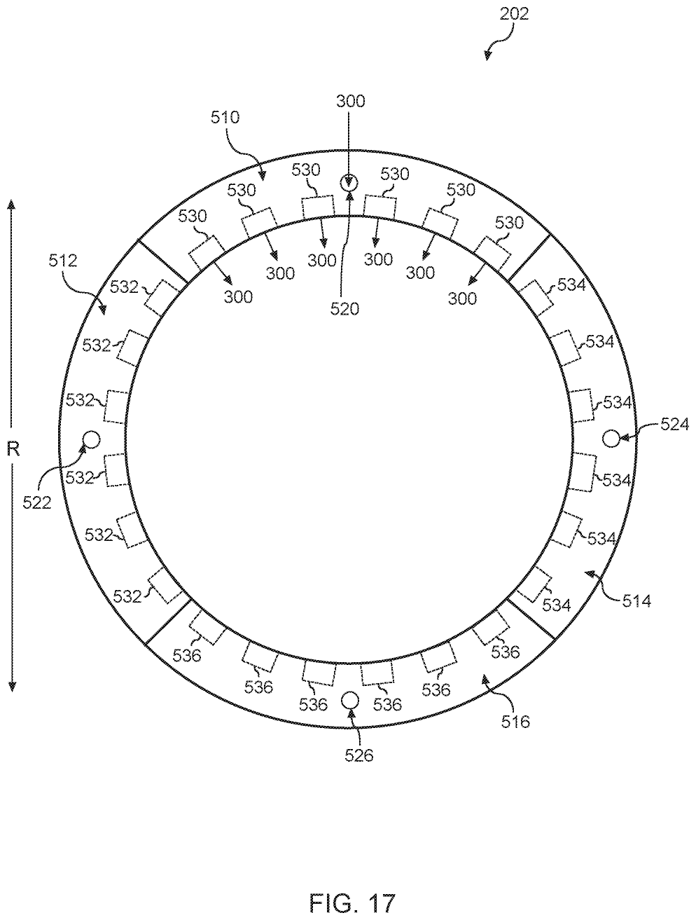

Referring now to FIG. 17, the first valve 540 (FIG. 16) can be actuated to or towards the open position to allow gas 300 to flow from the gas supply 150 to the first channel 510 defined by the gas delivery system 202. More specifically, the gas 300 can enter the first channel 510 via the first inlet 520. The gas 300 can then exit the first channel 510 via the first plurality of outlets 530 in fluid communication the first inlet 520 via the first channel 510. In the embodiment depicted in FIG. 17, only the first valve 540 is in the open position. Thus, gas 300 is not provided to any of the remaining channels (e.g., second channel 512, third channel 514, fourth channel 516).

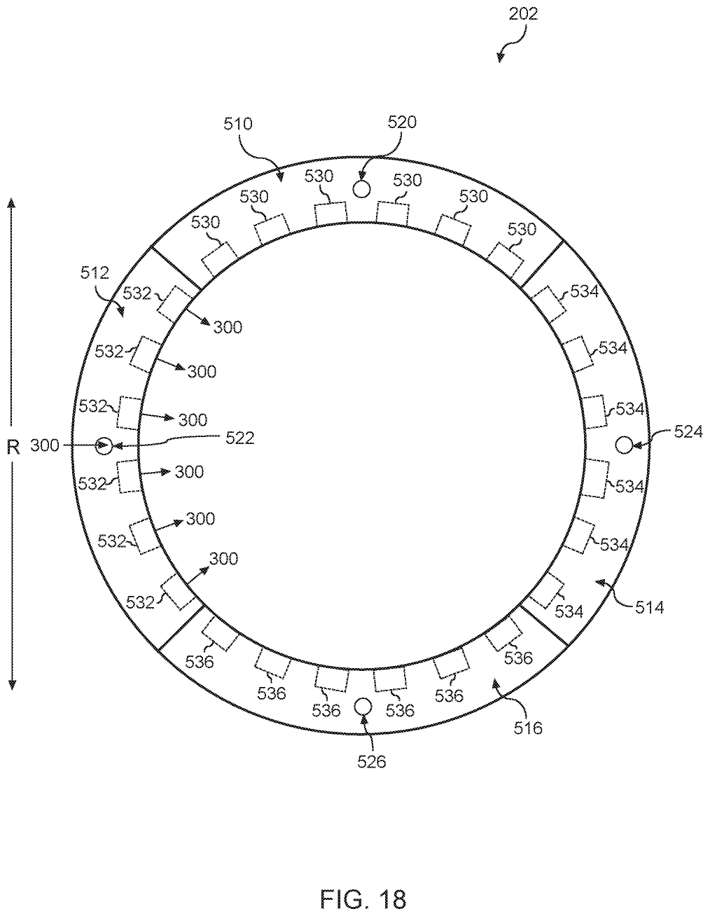

Referring now to FIG. 18, the second valve 542 (FIG. 16) can be actuated to or towards the open position to allow gas 300 to flow from the gas supply 150 to the second channel 512 defined by the gas delivery system 202. More specifically, the gas 300 can enter the second channel 512 via the second inlet 522. The gas 300 can then exit the second channel 512 via the second plurality of outlets 532 in fluid communication with the second inlet 522 via the second channel 512. In the embodiment depicted in FIG. 18, only the second valve 542 is in the open position. Thus, gas 300 is not provided to any of the remaining channels (e.g., first channel 510, third channel 514, fourth channel 516).

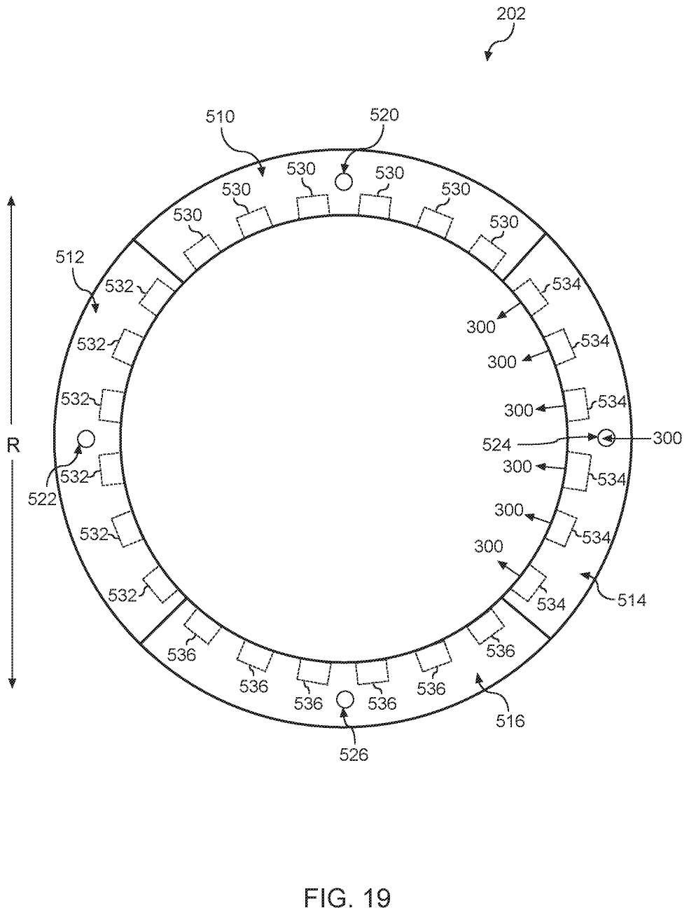

Referring now to FIG. 19, the third valve 544 (FIG. 16) can be actuated to the open position to allow gas 300 to flow from the gas supply 150 to the third channel 514 defined by the gas delivery system 202. More specifically, the gas 300 can enter the third channel 514 via the third inlet 524. The gas 300 can then exit the third channel 514 via the third plurality of outlets 534 in fluid communication with the third inlet 524 via the third channel 514. In the embodiment depicted in FIG. 19, only the third valve 544 is in the open position. Thus, gas 300 is not provided to any of the remaining channels (e.g., first channel 510, second channel 512, fourth channel 516).

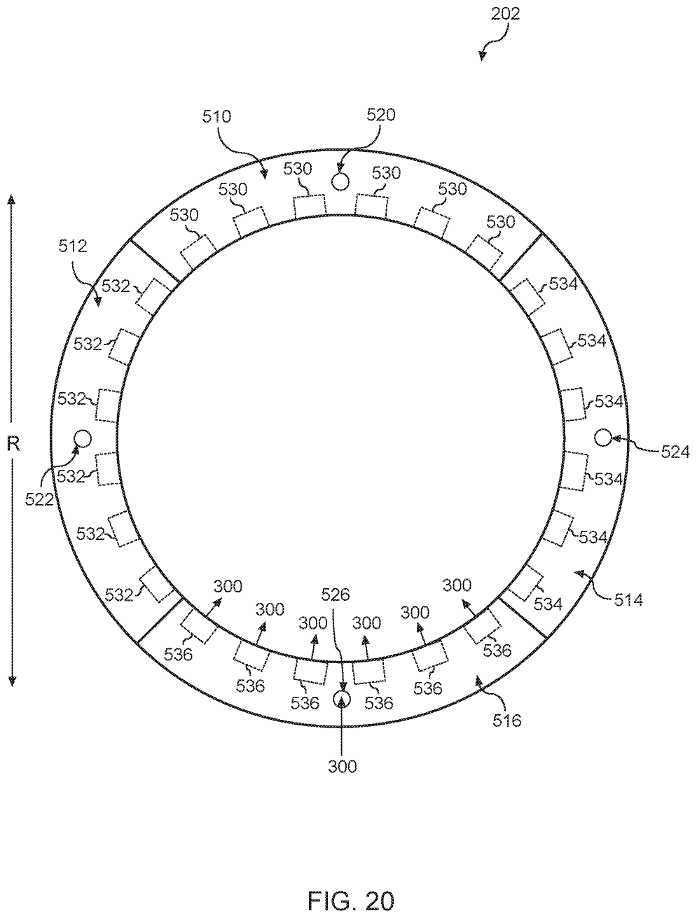

Referring now to FIG. 20, the fourth valve 546 (FIG. 16) can be actuated to the open position to allow gas 300 to flow from the gas supply 150 to the fourth channel 516 defined by the gas delivery system 202. More specifically, the gas 300 can enter the fourth channel 516 via the fourth inlet 526. The gas 300 can then exit the fourth channel 516 via the fourth plurality of outlets 536 in fluid communication with the fourth inlet 526 via the fourth channel 516. In the embodiment depicted in FIG. 20, only the fourth valve 546 is in the open position. Thus, gas 300 is not provided to any of the remaining channels (e.g., first channel 510, second channel 512, third channel 514).

It should be appreciated that any suitable combination of the valves 540, 542, 544, 546 can be actuated to the open position. For instance, in some implementations, the first valve 540 and at least one of the second valve 542, third valve 544 and fourth valve 546 can be actuated to the open position. In this manner, gas 300 can exit the gas delivery system 202 via the first plurality of outlets 530 and at least one of the second plurality of outlets 532, third plurality of outlets 534 and fourth plurality of outlets 536 to reduce or eliminate non-uniformities (e.g., azimuthal uniformity control) associated with the treatment process performed on the workpiece 114 (FIG. 1) disposed within the processing chamber 110 (FIG. 1).

Example Plasma Processing Apparatus with Workpiece Holder Having Opening

Another example aspect of the present disclosure is directed to a plasma processing apparatus to make more effective pumping capability (e.g., a symmetric pumping) via an opening of a workpiece holder. Non-uniformities associated with a treatment process can have an impact on a treatment process performance. Thus, it can be desirable that the non-uniformities are reduced or eliminated.

For instance, in some embodiments, the opening can be located in a middle of the workpiece holder to evacuate gases from the plasma processing apparatus such that a symmetric pumping can be provided to make better pumping capability. As such, non-uniformities associated with a treatment process (e.g., etching process, strip treatment process, surface treatment process, etc.) performed on a workpiece disposed in the plasma processing apparatus.

In some embodiments, the opening can have multiple holes to evacuate gases from the plasma processing apparatus. As one example, the opening can have a production compatible cover. The cover can include multiple holes and can be located on a top surface of the opening. Additionally, the cover can also block some parts from dropping into a pump port to damage a pump that can evacuate gases from the plasma processing apparatus. As another example, the opening itself can have the multiple holes to evacuate gases from the plasma processing apparatus.

According to example aspects of the present disclosure, the plasma processing apparatus can include a processing chamber, a workpiece holder, and a pump port. The workpiece holder in the processing chamber can be operable to support a first workpiece and a second workpiece in the processing chamber. The workpiece holder can include a first processing station and a second processing station. The first processing station can be configured to support the first workpiece. The second processing station can be configured to support the second workpiece. The pump port can evacuate gasses from the processing chamber. The pump port can be located beneath the workpiece holder. The workpiece holder can include an opening located between the first processing station and the second processing station. The opening can provide a path to evacuate gasses from the processing chamber to the pump port. The opening can include a plurality of holes to evacuate gases from the processing chamber.

In some embodiments, the opening can include a cover having a plurality of holes. The cover can be located on a top surface of the opening. In some embodiments, the opening itself can be a plurality of holes.

In some embodiments, the plurality of holes can be uniformly distributed. For instance, the plurality of holes can have the same hole density and/or the same hole size.

In some embodiments, the plurality of holes can be non-uniformly distributed. As one example, a first portion of the plurality of holes can include a first hole density, and a second portion of the plurality of holes can include a second hole density. The first hole density can be different from the second hole density. Alternatively, and/or additionally, a diameter of each hole of a first portion of the plurality of holes can be different from a diameter of each hole of a second portion of the plurality of holes. Holes with bigger sizes can give more pumping capability and holes with smaller sizes will give a choking effect.

In some embodiments, the cover can be removable and/or controllable for the symmetric pumping. Various covers can have different hole distributions (e.g., hole densities, hole sizes). For instance, a first cover can have a first plurality of same or different hole densities and a first plurality of same or different hole sizes. A second cover can have a second plurality of same or different hole densities and a second plurality of same or different hole sizes. The first plurality of hole densities and the first plurality of hole sizes can be different from the second plurality of hole densities and the second plurality of hole sizes, respectively. In some embodiments, during steps of a particular treatment process and/or various treatment processes a first cover can be removed from the opening, and a second cover can be placed on the opening for a second step of the particular treatment process and/or a second treatment process. In some embodiments, during a process test, multiple covers can be used for testing. One or more covers from the multiple covers can be selected to reduce non-uniformities associated with a treatment process (e.g., etching process, strip treatment process, surface treatment process, etc.) performed on a workpiece disposed in the plasma processing apparatus.

In some embodiments, the opening can be in a rectangular shape located between the first processing station and the second processing station. For instance, the cover of the opening and/or the opening itself can be in a rectangular shape. In some embodiments, the opening can include a first curved surface and a second opposing curved surface. The first curved surface can match an edge portion of the first processing station. The second opposing curved surface can match an edge portion of the second processing station. For instance, the cover of the opening and/or the opening itself can include the first curved surface and the second opposing curved surface. It should be appreciated, however, that opening can be in an arbitrary shape that is configured to provide effective pumping capability (e.g., symmetric pumping).

In some embodiments, the plasma processing apparatus can include a plasma chamber disposed above the processing chamber. The plasma chamber can be separated from the processing chamber via a separation grid (e.g., separation grid 200 as discussed in FIG. 1 through FIG. 20). The plasma processing apparatus can further include a first plasma chamber disposed above the first processing station. The first plasma chamber can be associated with a first inductive plasma source. The first plasma chamber can be separated from the processing chamber by a first separation grid (e.g., separation grid 200 as discussed in FIG. 1 through FIG. 20). A second plasma chamber can be disposed above the second processing station. The second plasma chamber can be associated with a second inductive plasma source. The second plasma chamber can be separated from the processing chamber by a second separation grid (e.g., separation grid 200 as discussed in FIG. 1 through FIG. 20).

Example aspects of the present disclosure provide a number of technical effects and benefits. For instance, an opening located in a middle of a workpiece holder can provide more effective pumping capability (e.g., a symmetric pumping), thereby, reducing non-uniformities associated with a treatment process (e.g., etching process, strip treatment process, surface treatment process, etc.) performed on a workpiece disposed in a plasma processing apparatus. In addition, the opening can have a removable and/or controllable cover that has a plurality of holes to provide a path to evacuate gasses from a processing chamber. As such, a desirable cover can be selected for providing better effective pumping capability and/or reducing non-uniformities associated with a treatment process.

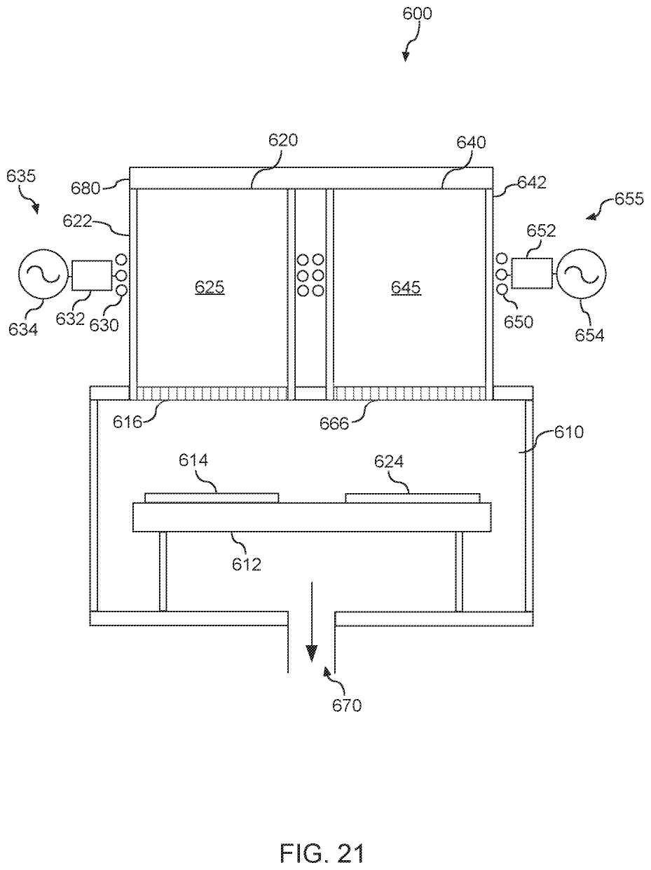

FIG. 21 depicts an example twin chamber plasma processing apparatus 600 according to example embodiments of the present disclosure. The twin chamber plasma processing apparatus 600 includes a processing chamber 610 and a first plasma chamber 620 (e.g., first plasma head) that is separate from the processing chamber 610. The twin chamber plasma processing apparatus 600 can include a second plasma chamber 640 (e.g., second plasma head) that can be substantially identical to the first plasma chamber 620. A top plate 680 can be disposed above the first plasma chamber 620 and the second plasma chamber 640.

The first plasma chamber 620 can include a dielectric sidewall 622. The top plate 680 and dielectric sidewall 622 can form a first plasma chamber interior 625. Dielectric sidewall 622 can be formed from any suitable dielectric material, such as quartz.

The twin chamber plasma processing apparatus 600 can include a first inductively coupled plasma source 635 configured to generate a plasma in a process gas provided to the first plasma chamber interior 625. The first inductively coupled plasma source 635 can include induction coil 630 disposed about the dielectric sidewall 622. The induction coil 630 can be coupled to an RF power generator 634 through a suitable matching network 632. Reactant and/or carrier gases can be provided to the chamber interior from a gas supply (not illustrated). When the induction coil 630 is energized with RF power from the RF power generator 634, a substantially inductive plasma is induced in the first plasma chamber interior 625. In some embodiments, the first plasma chamber 620 can include a grounded Faraday shield to reduce capacitive coupling of the induction coil 630 to the plasma.

The second plasma chamber 640 can include a dielectric sidewall 642. The top plate 680 and dielectric sidewall 642 can form a second plasma chamber interior 645. Dielectric sidewall 642 can be formed from any suitable dielectric material, such as quartz.

The twin chamber plasma processing apparatus 600 can include a second inductively coupled plasma source 655 configured to generate a plasma in a process gas provided to the second plasma chamber interior 645. The second inductively coupled plasma source 655 can include induction coil 650 disposed about the dielectric sidewall 642. The induction coil 650 can be coupled to an RF power generator 654 through a suitable matching network 652. Reactant and/or carrier gases can be provided to the second plasma chamber interior 645 from a gas supply (not illustrated). When the induction coil 650 is energized with RF power from the RF power generator 654, a substantially inductive plasma is induced in the second plasma chamber interior 645. In some embodiments, the second plasma chamber interior 645 can include a grounded Faraday shield to reduce capacitive coupling of the induction coil 650 to the plasma.

A first separation grid 116 can separate the first plasma chamber 620 from the processing chamber 610. The first separation grid 616 can be used to perform ion filtering of particles generated by plasma in the first plasma chamber 620. Particles passing through the first separation grid 616 can be exposed to a workpiece (e.g., a semiconductor wafer) in the processing chamber for surface treatment of the workpiece (e.g., photoresist removal).

More particularly, in some embodiments, the first separation grid 616 can be transparent to neutral species but not transparent to charged particles from the plasma. For example, charged particles or ions can recombine on walls of the first separation grid 616. The first separation grid 616 can include one or more grid plates of material with holes distributed according to a hole pattern for each sheet of material. The hole patterns can be the same or different for each grid plate.

For example, the holes can be distributed according to a plurality of hole patterns on a plurality of grid plates arranged in a substantially parallel configuration such that no hole allows for a direct line of sight between the plasma chamber and the processing chamber to, for example, reduce or block UV light. Depending on the process, some or all of the grid can be made of a conductive material (e.g., Al, Si, SiC, etc.) and/or non-conductive material (e.g., quartz, etc.). In some embodiments, if a portion of the grid (e.g. a grid plate) is made of a conductive material, the portion of the grid can be grounded. In some embodiments, the first separation grid 616 can be the separation grid 200 having a gas delivery system 202.

A second separation grid 666 can separate the second plasma chamber 640 from the processing chamber 610. The second separation grid 666 can be used to perform ion filtering of particles generated by plasma in the second plasma chamber 640. Particles passing through the second separation grid 666 can be exposed to a workpiece (e.g., a semiconductor wafer) in the processing chamber for surface treatment of the workpiece (e.g., photoresist removal).

More particularly, in some embodiments, the second separation grid 666 can be transparent to neutral species but not transparent to charged particles from the plasma. For example, charged particles or ions can recombine on walls of the second separation grid 666. The second separation grid 666 can include one or more grid plates of material with holes distributed according to a hole pattern for each sheet of material. The hole patterns can be the same or different for each grid plate.

For example, the holes can be distributed according to a plurality of hole patterns on a plurality of grid plates arranged in a substantially parallel configuration such that no hole allows for a direct line of sight between the plasma chamber and the processing chamber to, for example, reduce or block UV light. Depending on the process, some or all of the grid can be made of a conductive material (e.g., Al, Si, SiC, etc.) and/or non-conductive material (e.g., quartz, etc.). In some embodiments, if a portion of the grid (e.g. a grid plate) is made of a conductive material, the portion of the grid can be grounded. In some embodiments, the second separation grid 666 can be the separation grid 200 having a gas delivery system 202.

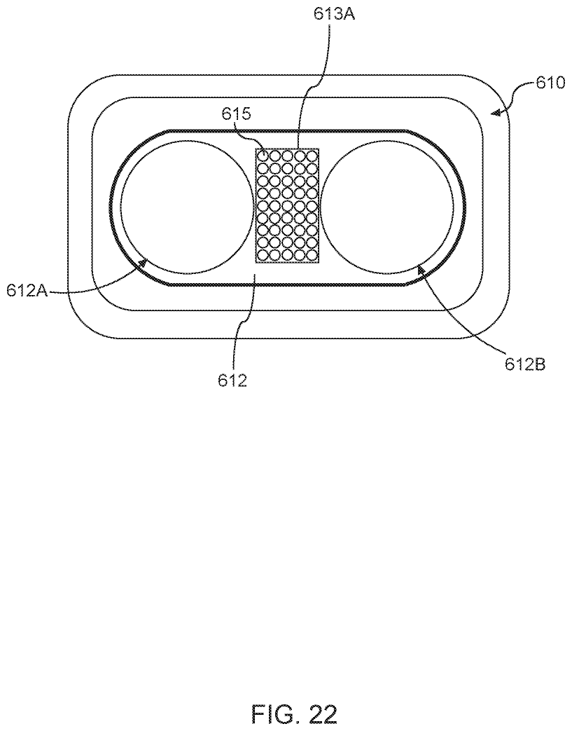

The plasma processing apparatus includes a workpiece holder 612 (e.g., a pedestal) operable to support a first workpiece 614 and a second workpiece 624 in the processing chamber 610. The workpiece holder 612 can include a first processing station and a second processing station (shown in FIG. 22). The first processing station can support the first workpiece 614. The second processing station can support the second workpiece 624.

The plasma processing apparatus includes a pump port 670 to evacuate gasses from the processing chamber 610. The pump port 670 is located beneath the workpiece holder 612. The workpiece holder 612 can include an opening located between the first processing station and the second processing station (shown in FIG. 22). The opening can provide a path to evacuate gasses from the processing chamber 610 to the pump port 670. The opening can include a plurality of holes to evacuate gases from the processing chamber 610.

FIG. 22 depicts a plan view of an example processing chamber 610 of a twin chamber plasma processing apparatus 600 according to example embodiments of the present disclosure. The workpiece holder 612 includes a first processing station 612A and a second processing station 612B. The first processing station 612A supports the first workpiece 614. The second processing station 612B supports the second workpiece 624. The workpiece holder 612 includes an opening 613A located between the first processing station 612A and the second processing station 612B, e.g., located in a middle of the workpiece holder 612. The opening 613A is in a rectangular shape.

As shown in FIG. 22, the opening includes a plurality of holes 615 to evacuate gases from the processing chamber 610. The plurality of holes 615 is uniformly distributed having the same hole density and the same hole size.

In some embodiments, the opening 613A can include a cover having the plurality of holes 615. The cover can be located on a top surface of the opening 613A. The cover can be removable and/or controllable for the symmetric pumping. In some embodiments, the opening 613A itself can have the plurality of holes 615.

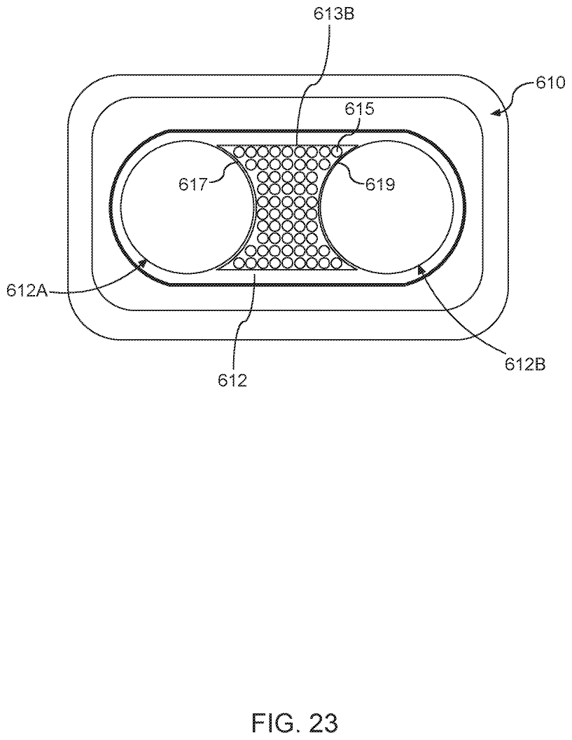

FIG. 23 depicts a plan view of an example processing chamber 610 of a twin chamber plasma processing apparatus 600 according to example embodiments of the present disclosure. As shown in FIG. 23, an opening 613B is located between the first processing station 612A and the second processing station 612B, e.g., located in a middle of the workpiece holder 612. The opening 613B includes a first curved surface 617 and a second opposing curved surface 619. The first curved surface 617 matches an edge portion of the first processing station 612A. The second opposing curved surface matches an edge portion of the second processing station 612B.

As shown in FIG. 23, the opening includes a plurality of holes 615 to evacuate gases from the processing chamber 610. The plurality of holes 615 is uniformly distributed having the same hole density and the same hole size.

In some embodiments, the opening 613B can include a cover having the plurality of holes 615. The cover can be located on a top surface of the opening 613B. The cover can be removable and/or controllable for the symmetric pumping. In some embodiments, the opening 613B itself can have the plurality of holes 615.

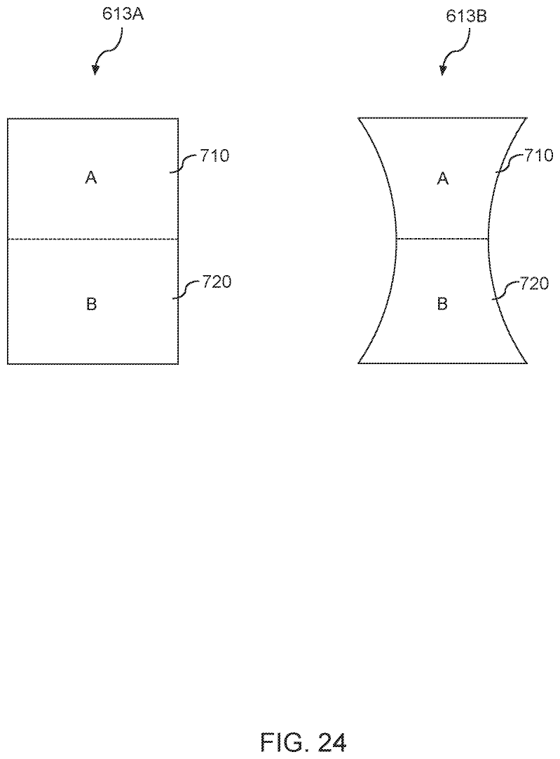

In some embodiments (not shown in FIG. 22 and FIG. 23), the plurality of holes 615 can be non-uniformly distributed. As one example, a first portion of the plurality of holes 615 can include a first hole density, and a second portion of the plurality of holes can include a second hole density. The first hole density can be different from the second hole density. Alternatively, and/or additionally, a diameter of each hole of a first portion of the plurality of holes 615 can be different from a diameter of each hole of a second portion of the plurality of holes 615. Holes with bigger sizes can give more pumping capability and holes with smaller sizes will give some choking effect and make them less pumping capability. Examples of a workpiece holder having non-uniformly distributed holes are further described in FIG. 24 through FIG. 27.

FIG. 24 depicts example openings 613A and 613B according to example embodiments of the present disclosure. An opening 613A and an opening 613B have a first portion A 710 and a second portion B 720 that are divided by a horizontal dash line. The first portion A 710 is located above the horizontal dash line. The second portion B 720 is located below the horizontal dash line. Holes in the first portion A 710 can include a first hole density, and holes in the second portion B 720 can include a second hole density. The first hole density can be different from the second hole density. Alternatively, and/or additionally, a diameter of each hole of the first portion A 710 can be different from a diameter of each hole of the second portion B 720.

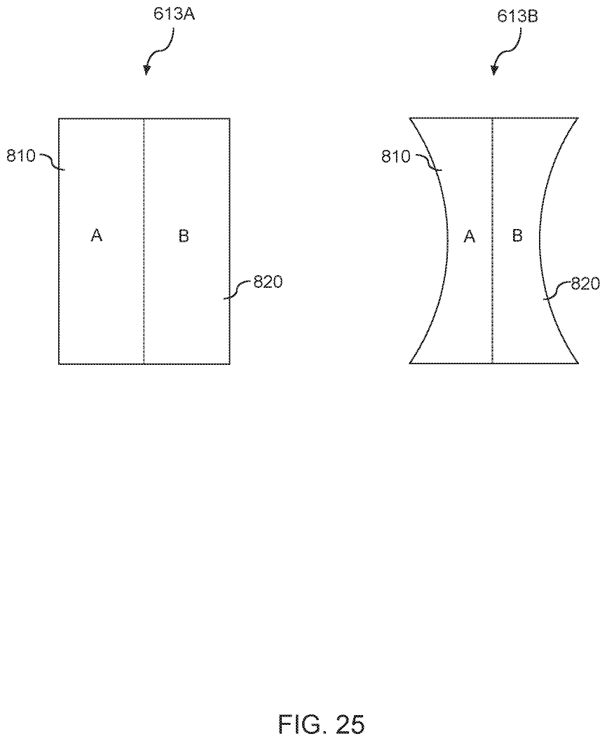

FIG. 25 depicts example openings 613A and 613B according to example embodiments of the present disclosure. An opening 613A and an opening 613B have a first portion A 810 and a second portion B 820 that are divided by a vertical dash line. The first portion A 810 is located on a left side of the vertical dash line. The second portion B 820 is located on a right side of the vertical dash line. Holes in the first portion A 810 can include a first hole density, and holes in the second portion B 820 can include a second hole density. The first hole density can be different from the second hole density. Alternatively, and/or additionally, a diameter of each hole of the first portion A 810 can be different from a diameter of each hole of the second portion B 820.

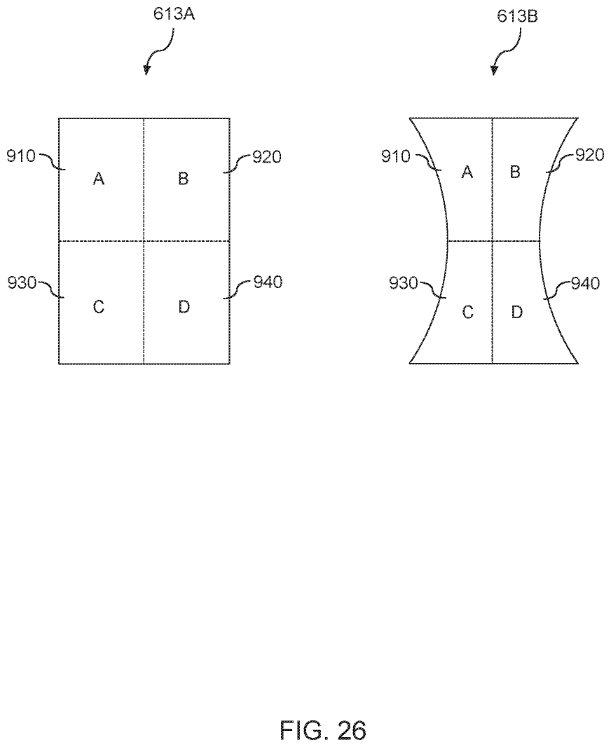

FIG. 26 depicts example openings 613A and 613B according to example embodiments of the present disclosure. An opening 613A and an opening 613B have a first portion A 910, a second portion B 920, a third portion C 930, and a fourth portion D 940 that are divided by a vertical dash line and a horizontal dash line. The first portion A 910 is located on a left side of the vertical dash line and above the horizontal dash line. The second portion B 920 is located on a right side of the vertical dash line and above the horizontal dash line. The third portion C 930 is located on a left side of the vertical dash line and beneath the horizontal dash line. The fourth portion D 940 is located on the right side of the vertical dash line and beneath the horizontal dash line. Holes in one or more of the first portion A 910, the second portion B 920, the third portion C 930, and the fourth portion D 940 can have different hole densities. Alternatively, and/or additionally, holes in one or more of the first portion A 910, the second portion B 920, the third portion C 930, and the fourth portion D 940 can have different diameters.

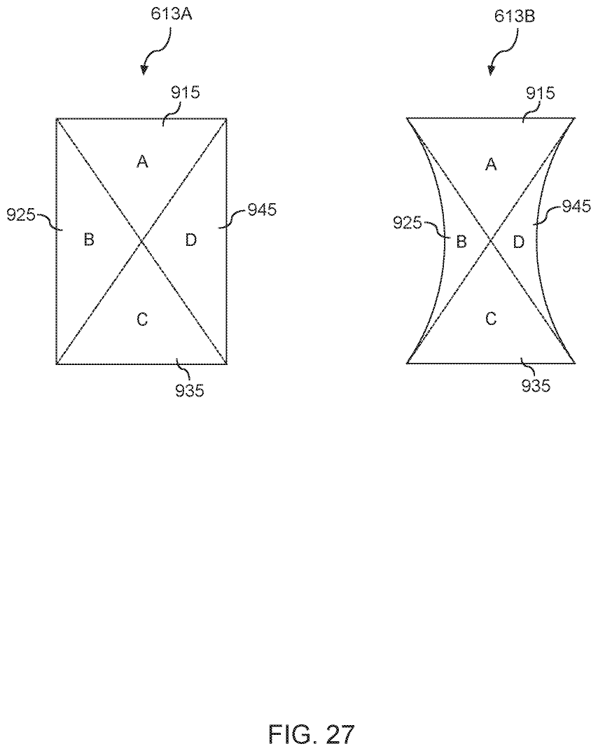

FIG. 27 depicts example openings 613A and 613B according to example embodiments of the present disclosure. An opening 613A and an opening 613B have a first portion A 915, a second portion B 925, a third portion C 935, and a fourth portion D 945 that are divided by a first diagonal dash line and a second diagonal dash line. Holes in one or more of the first portion A 915, the second portion B 925, the third portion C 935, and the fourth portion D 945 can have different hole densities. Alternatively, and/or additionally, holes in one or more of the first portion A 915, the second portion B 925, the third portion C 935, and the fourth portion D 945 can have different diameters.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus, comprising:
a plasma chamber;
a processing chamber comprising a substrate holder operable to support a substrate;
a plasma source configured to generate plasma in the plasma chamber; and
a separation grid separating the plasma chamber from the processing chamber, the separation grid comprising:
a gas delivery system defining a channel, an inlet, and a plurality of outlets in fluid communication with the inlet via the channel,
wherein the gas delivery system is configured to reduce non-uniformities associated with a treatment process performed on the substrate.

2. The plasma processing apparatus of claim 1, wherein the treatment process comprises an etching process, a strip treatment process, or a surface treatment process.

3. The plasma processing apparatus of claim 1, wherein:
the inlet is defined by a first portion of the gas delivery system;
a first group of outlets of the plurality of outlets are defined by the first portion of the gas delivery system; and
a second group of outlets of the plurality of outlets are defined by a second portion of the gas delivery system, the second portion being different than the first portion.

4. The plasma processing apparatus of claim 3, wherein a diameter of each outlet included in the first group of outlets is less than a diameter of each outlet included in the second group of outlets.

5. The plasma processing apparatus of claim 3, wherein a diameter of an outlet included in the first group of outlets and positioned adjacent the inlet is less than a diameter of every other outlet included in the first group of outlets.

6. The plasma processing apparatus of claim 5, wherein the diameter of the outlet is less than a diameter of every outlet included in the second group of outlets.

7. The plasma processing apparatus of claim 3, wherein the portion of the channel defined by the first portion of the gas delivery system is narrower than the portion of the channel defined by the second portion of the gas delivery system.

8. The plasma processing apparatus of claim 3, wherein the portion of the channel defined by the first portion of the gas delivery system is wider than the portion of the channel defined by the second portion of the gas delivery system.

9. The plasma processing apparatus of claim 3, further comprising:
a blocking material positioned over one or more outlets of the plurality of outlets.

10. The plasma processing apparatus of claim 9, wherein the blocking material is positioned over the first group of outlets defined by the first portion of the gas delivery system.

11. The plasma processing apparatus of claim 9, wherein the blocking material is positioned over the second group of outlets defined by the second portion of the gas delivery system.

12. The plasma processing apparatus of claim 1, wherein the gas delivery system includes a wall dividing the channel into a first channel and a second channel.

13. The plasma processing apparatus of claim 12, wherein the wall defines a plurality of openings to provide fluid communication between the first channel and the second channel.

14. The plasma processing apparatus of claim 12, wherein:
the inlet is in fluid communication with the first channel; and
the plurality of outlets are in fluid communication with the second channel.

15. A plasma processing apparatus, comprising:
a processing chamber;
a workpiece holder in the processing chamber operable to support a first workpiece and a second workpiece in the processing chamber, the workpiece holder comprising a first processing station and a second processing station, the first processing station configured to support the first workpiece, the second processing station configured to support the second workpiece;
a pump port configured to evacuate gasses from the processing chamber, the pump port located beneath the workpiece holder; and
wherein the workpiece holder comprises an opening located between the first processing station and the second processing station, the opening providing a path to evacuate gasses from the processing chamber to the pump port, the opening comprising a plurality of holes.

16. The plasma processing apparatus of claim 15, wherein the opening comprises a cover defining a plurality of holes.

17. The plasma processing apparatus of claim 16, wherein a first portion of the plurality of holes comprises a first hole density, and a second portion of the plurality of holes comprises a second hole density, wherein the first hole density is different from the second hole density.

18. The plasma processing apparatus of claim 15, wherein the opening comprises a first curved surface and a second opposing curved surface, the first curved surface matching an edge portion of the first processing station, the opposing second curved surface matching an edge portion of the second processing station.

19. The plasma processing apparatus of claim 15, further comprising:
a plasma chamber disposed above the processing chamber, the plasma chamber separated from the processing chamber via a separation grid.

20. A plasma processing apparatus, comprising
a plasma chamber;
a processing chamber comprising a substrate holder operable to support a substrate;
a plasma source configured to generate plasma in the plasma chamber;
a plurality of independently controllable valves; and
a separation grid separating the plasma chamber from the processing chamber, the separation grid comprising:
a gas delivery system defining a plurality of channels, a plurality of inlets and a plurality of outlets,
wherein each inlet of the plurality of inlets is coupled to a corresponding valve of the plurality of independently controllable valves, and
wherein the gas delivery system is configured such that gas exiting the channel via the plurality of outlets reduces non-uniformities associated with a treatment process performed on the substrate.
